(19) United States
(12) Patent Application Publication
(10) Pub. No.: US 2018/0371232 A1
(43) Pub. Date: Dec. 27, 2018

(54) Halogen-free Flame Retardant Resin Composition, Prepreg and Copper Clad Laminate Prepared Therefrom

(71) Applicant: SHENGYI TECHNOLOGY CO., LTD., Guangdong (CN)

(72) Inventors: Long XI, Guangdong (US); Jiang LI, Guangdong (CN); Yongjing XU, Guangdong (CN)

(21) Appl. No.: 15/736,998

(22) PCT Filed: Mar. 29, 2017
(86) PCT No.: PCT/CN2017/078501

§ 371 Date: Dec. 15, 2017

(30) Foreign Application Priority Data
Dec. 30, 2016 (CN) 201611262945.6

(51) Int. Cl. C08L 63/00; C08K 5/523; C08K 3/013; C08K 5/00; H05K 1/03

(52) U.S. Cl. CPC C08L 63/00; C08K 5/523; C08F 222/08; C08K 5/0025; H05K 1/0373; C08K 3/013

(57) ABSTRACT

The present invention relates to a halogen-free flame retardant resin composition, a prepreg and a copper clad laminate prepared therefrom. The composition of the present invention comprises, based on the weight parts of solid components, (A) from 5 to 80 parts by weight of alkylphenol epoxy resin, (B) from 10 to 80 parts by weight of benzoxazine resin, (C) from 2 to 30 parts by weight of styrene maleic anhydride resin, (D) from 1 to 30 parts by weight of a flame retardant, and (E) from 0.5 to 100 parts by weight of an acidic filler having a pH of 2-6. The present invention further provides a prepreg and a copper clad laminate prepared from the halogen-free flame retardant resin composition. While ensuring a higher glass transition temperature and excellent moisture heat resistance, the halogen-free flame retardant resin composition of the present invention effectively improves the dielectric properties and the peel strength stability of the resin composition, and provides the prepregs and copper clad laminates with excellent comprehensive performances.

### TECHNICAL FIELD

The present invention relates to the technical field of copper clad laminates, in particular to a halogen-free flame retardant resin composition, a prepreg and a copper clad laminate prepared therefrom.

### BACKGROUND ART

In order to achieve bromine-free flame retardancy, phosphorus-containing resins or flame retardants are usually used together with nitrogen-containing resins or flame retardants in the industry, so as to achieve phosphorus-bromine synergistic and efficient flame retardancy. Benzoxazine resin comprises nitrogen element. When it is used together with phosphorus element, the V-0 grade of UL 94 can be achieved with a lower phosphorus content. With low curing shrinkage and good resistance to moisture and heat, it has been widely used. However, the ring-opening polymerization needs a higher temperature due to the structural features of benzoxazine, which brings about difficulties to the industrialized mass production and becomes application difficulty thereof.

With the development of communication technology, the requirements on dielectric constant (Dk) and dielectric loss of printed circuit laminates (CCL) are increasing. It is well known that, when Dk is lower, Df is smaller, the transmission speed of signals on the substrates is faster, and the power loss of signals during the transmission remains consistent, the permitted frequencies of transmission are higher. In the field of consumer electronics represented by cell phone, laptops and tablet computer, the tendency of lightness, thinness, shortness and smallness will be further developed. In order to achieve thinner design without any decrease of the arithmetic speed, substrates having a lower dielectric constant/dielectric loss shall be necessarily developed. In recent years, more industry researches focus on how to reduce the dielectric constant/dielectric loss of substrates.

U.S. Pat. No. 6,509,414A1 discloses preparing copper clad laminates by using brominated epoxy resin, tetrabromo bisphenol A and styrene-maleic anhydride. Since C—Br bond contained therein has a lower bond energy, it readily fractures in an environment of higher than 200° C. to release small molecules, resulting in delamination. CN103421273A discloses curing epoxy resins by using benzoxazine resin, styrene-maleic anhydride and dicyclopentadiene phenolic resin, so as to reach the performances of low dielectric constant, low dielectric loss, high heat resistance and high flame retardancy. Due to the use of dicyclopentadiene phenolic resin, the content of hydroxyl in the resin composition cannot be effectively reduced, and the dielectric constant and dielectric loss are decreased in a limited extent.

CN101684191B and C103131131A both disclose using benzoxazine and styrene maleic anhydride for co-curing epoxy resins to obtain lower dielectric properties. However, when benzoxazine and styrene maleic anhydride are used as the composite curing agent of the epoxy resins, the polymerization of styrene maleic anhydride and epoxy resin needs lower temperature, while benzoxazine and epoxy resin needs higher temperature. Along with the increase of laminating temperature, two main reactions of styrene maleic anhydride and epoxy resin, as well as benzoxazine and epoxy resin, will occur one after another, and there will be 2-3 clear reaction exothermic peaks in the differential thermal scanning analysis diagram. Moreover, self-polymerization will readily occur when benzoxazine is at a high temperature. Such “complicated” situation will bring about reliability problems. Thus there are always problems in the application of benzoxazine.

### DISCLOSURE OF THE INVENTION

On such a basis, the object of the present invention is to provide a halogen-free flame retardant resin composition, a prepreg and a copper clad laminate prepared therefrom. The addition of acidic filler into the resin composition greatly promotes the polymerization of benzoxazine and epoxy resin, and decreases the curing temperature needed for the polymerization of benzoxazine and epoxy resin. The combination of alkylphenol epoxy resin with styrene maleic anhydride resin could achieve better dielectric properties. The acidic filler could make up its defect of weak interlayer binding force, so as to reach synergistic effects.

In order to achieve said object, the inventors made repeated and thorough studies and found that the composition obtained by mixing acidic filler with benzoxazine resin, alkylphenol epoxy resin and styrene maleic anhydride, as well as other optional substances may reach said object.

In order to achieve the aforesaid object, the present invention discloses the following technical solution.

In the first aspect, the present invention provides a halogen-free flame retardant resin composition, based on the weight parts of solid components, comprising the following components:
(A) from 5 to 80 parts by weight of alkylphenol epoxy resin,
(B) from 10 to 80 parts by weight of benzoxazine resin,
(C) from 2 to 30 parts by weight of styrene maleic anhydride resin,
(D) from 1 to 30 parts by weight of a flame retardant, and
(E) from 0.5 to 100 parts by weight of an acidic filler having a pH of 2-6.

In the present invention, the combination of alkylphenol epoxy resin with styrene maleic anhydride resin could achieve better dielectric properties. The addition of the acidic filler could make up its defect of weak interlayer binding force, so as to reach synergistic effects, effectively increase the dielectric properties and peeling strength stability of the resin composition and make the prepregs and printed circuit laminates have excellent comprehensive performances.

The present invention discloses that the addition of the acidic filler into the halogen-free flame retardant resin composition can not only catalyze the ring-opening polymerization of benzoxazine resin and epoxy resin, but also promote the self-crosslinking polymerization of benzoxazine, and greatly decrease the temperature needed for the polymerization of benzoxazine and epoxy resin. In addition, the acidic filler has a melting point as high as more than 1000° C., and will not volatilize due to heating in the process of producing copper clad laminates or decompose during the PCB processing, so as to resolve the defects of organic acids and common inorganic acids in resins. Furthermore, the acidic filler in the resin composition can also decrease the CTE (coefficient of thermal expansion) of the products. It is advantageous to the reliability of the articles if the acidic filler could retain in the resin composition.

According to the present invention, said alkylphenol epoxy resin has the structure as follows:

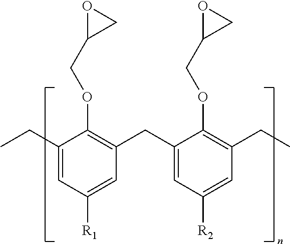

wherein R₁ and R₂ are each independently selected from substituted or unsubstituted linear alkyl or branched alkyl having a carbon atom number of 4-8, e.g. n-butyl, n-pentyl, n-octyl, isobutyl, isopentyl and the like, preferably n-butyl or n-octyl; n is an integer of 2-20, e.g. 2, 3, 4, 5, 6, 7, 8, 9, 12, 15, 18 or 20.

In the halogen-free flame retardant resin composition of the present invention, said alkylphenol epoxy resin is in an amount of from 5 to 80 parts by weight, e.g. 5, 10, 12, 15, 18, 20, 22, 25, 28, 30, 32, 40, 45, 55, 60, 65, 70, 75 or 80 parts by weight, and any specific point values between said values above. Due to space limitations and for concise consideration, the present invention will not exhaustively list any specific point values included in the range, and said alkylphenol epoxy resin is preferably in an amount of 10 to 35 parts by weight.

According to the present invention, said benzoxazine resin, also known as compounds having dihydrobenzoxazine ring, is a benzo six-membered heterocyclic compound and can produce a nitrogen-containing network structure similar to phenolic resin by ring-opening polymerization. In the present invention, benzoxazine resin can increase the flame retardancy, moisture resistance, heat resistance, mechanical performance and higher glass transition temperature (Tg) needed for the halogen-free flame retardant resin composition, as well as the prepregs and laminates obtained therefrom.

In the present invention, said benzoxazine resin is anyone selected from the group consisting of bisphenol A type benzoxazine resin, dicyclopentadiene benzoxazine resin, bisphenol F type benzoxazine resin, phenolphthalein benzoxazine resin and MDA type benzoxazine resin, or a mixture of at least two selected therefrom. The typical but non-limitative mixture is selected from the group consisting of the mixtures of bisphenol A type benzoxazine resin and dicyclopentadiene benzoxazine resin, dicyclopentadiene benzoxazine resin and bisphenol F type benzoxazine resin, bisphenol F type benzoxazine resin and phenolphthalein benzoxazine resin.

Said bisphenol A type benzoxazine resin monomer, bisphenol F type benzoxazine resin monomer and phenolphthalein benzoxazine resin monomer have the following structure as shown in Formula (a)

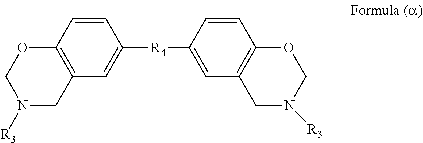

wherein R₃ is

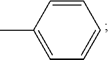

R₄ is anyone selected from the group consisting of

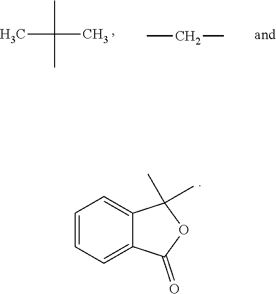

When R₄ is

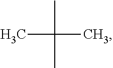

Formula (α) represents bisphenol A type benzoxazine resin monomer; when R₄ is —CH₂—, Formula (α) represents bisphenol F type benzoxazine resin monomer; when R₄ is

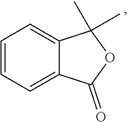

Formula (α) represents phenolphthalein benzoxazine resin monomer.

Said MDA type benzoxazine resin, also known as (4,4′-diaminodiphenylmethane) type benzoxazine resin, has the following structure as shown in Formula (β),

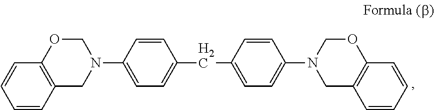 [SMILES: c1ccc2c(c1)CN(c1ccc(Cc3ccc(N4COc5ccccc5C4)cc3)cc1)CO2]

Said dicyclopentadiene benzoxazine resin monomer has the following structure as shown in Formula (γ),

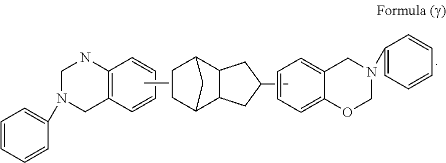

In the halogen-free flame retardant resin composition of the present invention, said benzoxazine resin is in an amount of from 10 to 80 parts by weight, e.g. 10, 12, 15, 18, 20, 22, 25, 28, 30, 32, 40, 45, 55, 60, 65, 70, 75 or 80 parts by weight, and any specific point values between said values above. Due to space limitation and for concise consideration, the present invention will not exhaustively list any specific point values included in the range, and said benzoxazine resin is preferably in an amount of 30 to 65 parts by weight.

In the halogen-free flame retardant resin composition of the present invention, the styrene chain segment units and maleic anhydride chain segment units have a ratio of 8:1-1:1 in said styrene maleic anhydride resin, e.g. 8:1, 7:1, 6:1, 5:1, 4:1, 3:1, 2:1 or 1:1, and any specific point values between said values above. Due to space limitation and for concise consideration, the present invention will not exhaustively list any specific point values included in the range.

In the halogen-free flame retardant resin composition of the present invention, said styrene maleic anhydride resin is in an amount of 2-30 parts by weight, e.g. 2, 5, 8, 10, 12, 15, 18, 20, 22, 25, 28 or 30 parts by weight, and any specific point values between said values above. Due to space limitation and for concise consideration, the present invention will not exhaustively list any specific point values included in the range, and said styrene maleic anhydride resin is preferably in an amount of 5-20 parts by weight.

In the present invention, said flame retardant is anyone selected from the group consisting of resorcinol-bis(diphenyl phosphate), bisphenol A-bis(diphenyl phosphate), resorcinol-bis(2,6-dimethylphenyl phosphate), dimethyl methyl phosphonate and phosphazene compounds, or a mixture of at least two selected therefrom. The typical but non-limitative mixture is selected from the group consisting of the mixtures of resorcinol-bis(diphenyl phosphate) and bisphenol A-bis(diphenyl phosphate), bisphenol A-bis(diphenyl phosphate) and resorcinol-bis(2,6-dimethylphenyl phosphate), resorcinol-bis(2,6-dimethylphenyl phosphate) and dimethyl methyl phosphonate, and dimethyl methyl phosphonate and phosphazene compounds.

According to the present invention, said flame retardant is in an amount of 1-30 parts by weight, e.g. 1, 2, 5, 8, 10, 15, 20, 25, 28 or 30 parts by weight, and any specific point values between said values above. Due to space limitation and for concise consideration, the present invention will not exhaustively list any specific point values included in the range, and said flame retardant is preferably in an amount of 3-20 parts by weight.

In the present invention, said acidic filler is anyone selected from the group consisting of silica powder, quartz powder, mica powder, clay, calcium oxalate and carbon black, or a mixture of at least two selected therefrom. The typical but non-limitative mixture is selected from the group consisting of the mixtures of silica powder and quartz powder, clay and calcium oxalate, and carbon black and mica powder.

In the present invention, said acidic filler has a particle size of 50 nm-50 μm, e.g. 50 nm, 60 nm, 70 nm, 80 nm, 90 nm, 100 nm, 300 nm, 500 nm, 800 nm, 5 μm, 10 μm, 30 μm, 40 μm, 45 μm or 50 μm, and any specific point values between said values above. Due to space limitation and for concise consideration, the present invention will not exhaustively list any specific point values included in the range.

The present invention does not make any specific definitions to the physical form of said acidic filler, and it may be sheet-shaped, rod-shaped, spherical, hollow spherical, granular, fibrous or plate-shaped. Selectively, said acidic filler is treated with a silane coupling agent.

According to the present invention, said acidic filler is added in an amount of 0.5-100 parts by weight in the halogen-free flame retardant resin composition, e.g. 0.5, 0.8, 1, 10, 20, 30, 40, 55, 60, 65, 70, 80, 90 or 100 parts by weight, and any specific point values between said values above. Due to space limitation and for concise consideration, the present invention will not exhaustively list any specific point values included in the range, and said acidic filler is preferably in an amount of 5-60 parts by weight.

The acidic filler of the present invention is added in an amount of 5-60 parts by weight as the preferred amount. The inventors found upon research that, if the filler is in an amount of higher than 60 parts by weight, the resin composition as a whole will have a stronger acidity, an obviously accelerated ring-opening polymerization of benzoxazine-epoxy system, which will narrow the processing window of the resin composition. If the filler is in an amount of lower than 5 parts by weight, the resin composition as a whole will have a weaker acidity and an inapparent catalytic effect on benzoxazine-epoxy system.

According to the present invention, said acidic filler has a pH of 2-6, e.g. 2, 2.5, 3, 3.5, 4, 5 or 6, and any specific point values between said values above. Due to space limitation and for concise consideration, the present invention will not exhaustively list any specific point values included in the range.

In the present invention, the acidic filler is characterized in formulating an aqueous solution by using such filler and deionized water at a mass ratio of 1:9, measuring to obtain that the filler has a pH of 2-6.

Preferably, said acidic filler of the present invention has a pH of 4-6.

According to the present invention, the halogen-free flame retardant resin composition may further comprise a non-acidic filler.

Preferably, said non-acidic filler is anyone selected from the group consisting of calcium carbonate, calcium sulfate, alumina, barium sulfate, ceramic powder, talc powder and hydrotalcite, or a mixture of at least two selected therefrom. The typical but non-limitative mixture is selected from the group consisting of the mixtures of calcium carbonate and calcium sulfate, alumina and barium sulfate, talc powder and ceramic powder.

Preferably, said non-acidic filler is added in an amount of 0-100 parts by weight, e.g. 1, 5, 15, 30, 45, 58, 62, 78, 89 or 100 parts by weight, as well as any specific point values between said values. Due to space limitation and for concise consideration, the present invention will not exhaustively list any specific point values included in the range.

According to the present invention, said halogen-free flame retardant resin composition further comprises (F) a curing accelerator. Based on 100 parts by weight of organic solids in said halogen-free flame retardant resin composition, said curing accelerator is added in an amount of 0.1-1 part by weight, e.g. 0.1, 0.2, 0.3, 0.4, 0.5, 0.6, 0.7, 0.8, 0.9 or 1 part by weight, as well as any specific point values between said values. Due to space limitation and for concise consideration, the present invention will not exhaustively list any specific point values included in the range.

In the present invention said curing accelerator is anyone selected from the group consisting of imidazole accelerators and their derivatives, pyridine accelerators and Lewis acid accelerators, or a mixture of at least two selected therefrom. The typical but non-limitative mixture is selected from the group consisting of the mixtures of imidazole accelerators and pyridine accelerators, pyridine accelerators and Lewis acid accelerators, imidazole accelerators and Lewis acid accelerators.

Preferably, said imidazole accelerator is anyone selected from the group consisting of 2-methylimidazole, 2-ethyl-4-methylimidazole, 2-phenylimidazole, and 2-undecylimidazole, or a mixture of at least two selected therefrom

The curing accelerator is beneficial for the curing reaction of epoxy resin, benzoxazine and curing agent, so as to form homogeneous three-dimensional network molecular structure, to achieve better physical properties, to promote the decrease of group concentrations of hydroxyl (—OH) and epoxy groups, to help the resin composition reach better dielectric properties, to decrease the dielectric constant and dielectric loss.

As a preferred technical solution, the halogen-free flame retardant resin composition, based on the weight parts of solid components, comprising the following components:
(A) from 10 to 35 parts by weight of alkylphenol epoxy resin,
(B) from 30 to 60 parts by weight of benzoxazine resin,
(C) from 5 to 20 parts by weight of styrene maleic anhydride resin,
(D) from 3 to 20 parts by weight of a flame retardant,
(E) from 5 to 60 parts by weight of an acidic filler having a pH of 2-6, and
(F) from 0.1 to 1 part by weight of a curing accelerator.

As for the process for preparing the halogen-free flame retardant resin composition in the present invention, those skilled in the art may make selection by reference to the current processes for preparing resin compositions in combination with actual situations. The present invention will not make any special definitions.

In the second aspect, the present invention further provides a process for preparing a halogen-free flame retardant resin composition, comprising:
adding an acidic filler having a pH of 2-6 into a halogen-free flame retardant resin composition;
said halogen-free flame retardant resin composition comprises alkylphenol epoxy resin, benzoxazine resin and styrene maleic anhydride resin.

By adding an acidic filler into a halogen-free flame retardant resin composition, the present invention greatly promotes the polymerization of benzoxazine and epoxy resin, decreases the curing temperature needed for the polymerization of benzoxazine and epoxy resin, and makes complete reaction of benzoxazine and epoxy resin. The laminates prepared from the halogen-free flame retardant resin composition added with an acidic filler have a higher anti-stripping stability, a higher glass transition temperature, a low water absorption, a high heat resistance, a high bending strength and a better processability, and can achieve a low coefficient of thermal expansion.

Alkylphenol epoxy resin of the present invention can be conducive to reducing the dielectric constant and dielectric loss factor of the system, increasing the tenacity of the composition and improving the drilling quality. Meanwhile, the combination of alkylphenol epoxy resin with styrene maleic anhydride resin could achieve better dielectric properties. The addition of the acidic filler could make up its defect of weak interlayer binding force, so as to reach synergistic effects of said three materials, effectively increase the dielectric properties and peeling strength stability of the resin composition and make the prepregs and printed circuit laminates have excellent comprehensive performances.

Those skilled in the art know that, besides alkylphenol epoxy resin, benzoxazine resin and styrene maleic anhydride resin, the preparation process of the halogen-free flame retardant resin composition further optionally comprises the components such as the flame retardant, non-acidic filler and curing accelerator in the first aspect of the present invention. Moreover, each component in the halogen-free flame retardant resin composition and contents thereof may illustratively refer to the ranges stated in the first aspect of the present invention.

The term “comprising/comprise(s)” in the present invention means that, in addition to said components, there may also include other components which impart different characteristics to the resin composition. In addition to this, the term “comprising/comprise(s)” in the present invention may be replaced by a closed-form “is/are” or “consisting/consist(s) of”.

For example, the halogen-free flame retardant resin composition may also comprise various additives, such as antioxidant, thermal stabilizer, anti-static agent, ultra-violet absorber, pigment, colorant, lubricant and the like. These additives may be used alone or in combination of two or more.

As for the preparation steps of the halogen-free flame retardant resin composition not further defined in the present invention, those skilled in the art may make selection by reference to the current processes for preparing resin compositions in combination with actual situations. The present invention will not make any special definitions.

The present invention further provides a prepreg comprising the halogen-free flame retardant resin composition stated in the first aspect, or the halogen-free flame retardant resin composition prepared according to the process in the second aspect, as well as a reinforcing material. The reinforcing material is not specifically defined, and it may be organic fibers, inorganic fiber woven fabrics, or non-woven fabrics. Said organic fibers may be aramid non-woven fabrics; said inorganic fiber woven fabrics may be E-glass fiber fabrics, D-glass fiber fabrics, S-glass fiber fabrics, T-glass fiber fabrics, NE-glass fiber fabrics, or quartz cloth. The thickness of the reinforcing material is not specifically defined. In consideration of better size stability of the laminates, the woven and non-woven fabrics have a thickness of preferably 0.01-0.2 mm, and are preferably subjected to fiber opening treatment and surface treatment with a silane coupling agent. In order to provide better water resistance and heat resistance, said silane coupling agent is preferably anyone selected from the group consisting of epoxy silane coupling agent, amino silane coupling agent and vinyl silane coupling agent, or a mixture of at least two selected therefrom. The reinforcing material is impregnated with the aforesaid composite material, baked at 100-250° C. for 1-15 min to obtain said prepregs.

The copper clad laminate for printed circuit board of the present invention comprises a laminate prepared by binding two or more prepregs together by heating and pressing, and metal foils bond to one or both sides of the laminate. The copper clad lamination shall satisfy the following requirements including (1) the temperature rising rate which should be controlled at 1.0-3.0° C./min at the material temperature which is 80-160° C.; (2) the pressure setting of the lamination: applying a full pressure of about 300 psi when the outer material temperature is 80-100° C.; and (3) controlling the material temperature at 185° C. during the curing and maintaining the temperature for 90 min. Metal foils to be overlapped can also be nickel foils, aluminium foils, SUS foils and the like, and the material is not defined therein.

As compared to the prior art, the present invention at least has the following beneficial effects.

(1) By adding an acidic filler into the halogen-free flame retardant resin composition, the present invention greatly promotes the polymerization of benzoxazine and epoxy resin, decreases the curing temperature needed for the polymerization of benzoxazine and epoxy resin, and makes complete reaction of benzoxazine and epoxy resin.

(2) The laminates prepared from the halogen-free flame retardant resin composition added with an acidic filler have a higher anti-stripping stability, a higher glass transition temperature, a low water absorption, a high heat resistance, a high bending strength and a better processability, and can achieve a low coefficient of thermal expansion.

(3) Alkylphenol epoxy resin of the present invention comprises more alkyl chain segments, which is conducive to reducing the dielectric constant and dielectric loss factor of the system. Moreover, more alkyl chain segments are good for increasing the tenacity of the composition, and improving the drilling quality. In addition, the combination of alkylphenol epoxy resin with styrene maleic anhydride resin could achieve better dielectric properties. The addition of the acidic filler could make up its defect of weak interlayer binding force, so as to reach synergistic effects of said three materials, effectively increase the dielectric properties and peeling strength stability of the resin composition and make the prepregs and printed circuit laminates have excellent comprehensive performances.

### EMBODIMENTS

The technical solutions of the present invention are further explained by the following embodiments.

The following refers to the specific embodiments of the present invention. It should be pointed out that, without departing from the principles of the examples of the present invention, a number of amendments and improvements can also be made for those ordinarily skilled in the art. Moreover, such amendments and improvements are also deemed as the protection scopes of the examples of the present invention.

The examples of the present invention are further stated below. The examples of the present invention are not limited to the following specific examples, and could be properly amended and carried out without changing the scopes of the claims.

Unless otherwise stated hereinafter, said “parts” refers to “weight parts”, and said “%” refers to “weight %”.

The materials and brands involved in the examples and comparison examples are provided as follows.
(A) Epoxy resin
   A1: alkylphenol epoxy resin, a product having the product model of KES-7595 and provided by KOLON;
   A2: DCPD epoxy, having the model of 7200H and purchased from DIC;
(B) Benzoxazine resin
   B1: a product having the model of LZ8290H62 and purchased from Huntsman;
   B2: a product having the model of D125 and purchased from EM Technology;
(C) Styrene Maleic Anhydride Resin
   C1: a product having the model of EF40 and purchased from Sartomer;
   C2: a product having the model of EF60 and purchased from Sartomer;
(D) Flame retardant
   D1: a product having the model of PX-200 and purchased from Daihachi Chemical;
   D2: a product having the model of SPB-100 and purchased from Otsuka Chemical;
(E) Filler
   E1: silica DQ-1030 having a pH=4.0 and purchased from Novoray;
   E2: mica powder GD-2 having a pH=5.0 and purchased from Gerui;
   E3: carbon black having a pH=3.0 and purchased from Tianjin Xinglongtai Chemical Products Technology Co., Ltd;
   E4: boehmite BG-615 having a pH=6.8 and purchased from Bengbu Xinyuan;
   E5: Silica MEGASIL525 having a pH=6.5 and purchased from Sibelco;
   E6: spherical silica power SC2500-SEJ having a pH pH=8.0 and purchased from Admatechs; and
(F) Curing accelerator
   F1: 2-phenylimidazole purchased from Shikoku Chemicals.

The resin compositions provided in the examples and comparison examples were used to prepare laminates for printed circuit according to the following method, and the performance test was carried out for the prepared laminates.

The laminates for printed circuit are prepared by
\textcircled{1} binding one or more prepregs together by heating and pressing to prepare a laminate;
\textcircled{2} binding metal foils to one or both sides of the laminate prepared in step 0;
\textcircled{3} laminating in a laminator;
   overlapping 8 sheets of prepregs and 2 sheets of metal foils in an amount of one ounce (having a thickness of 35 μm) during the step \textcircled{2};
   during the step \textcircled{3}, laminating at 80-140° C. which is the material temperature, a temperature rising rate of 1.5-2.5° C./min, applying a full pressure of about 350 psi when the outer material temperature is 80-100° C.; controlling the material temperature at 195° C. and maintaining the temperature for at least 60 min.

The formulations and performance test results of the resin compositions provided in the examples and comparison examples are stated in Tables 1-3.

TABLE 1

| | Example 1 | Example 2 | Example 3 | Example 4 | Example 5 | Example 6 |
|---|---|---|---|---|---|---|
| A1 | 20 | 20 | 50 | 50 | 80 | 80 |
| A2 | | | | | | |
| B1 | 80 | 80 | 50 | 50 | 20 | 20 |
| B2 | | | | | | |
| C1 | 10 | 10 | 15 | 0 | 30 | 30 |
| C2 | | | | 20 | | |
| D1 | 10 | 10 | 20 | 20 | 30 | 30 |
| D2 | | | | | | |
| E1 | 40 | 50 | 50 | 20 | 10 | 50 |
| E2 | | | | | | |
| E3 | | | | | | |
| E4 | | | | | | |
| E5 | | | | | | |
| E6 | | | | | | |
| F | 0.2 | 0.2 | 0.2 | 0.2 | 0.2 | 0.2 |
| Number of | 1 | 1 | 1 | 1 | 1 | 1 |
| DSC peaks | | | | | | |
| Glass transition | 183 | 191 | 168 | 173 | 158 | 165 |
| temperature | | | | | | |
| (Tg, ° C.) | | | | | | |
| Flame | V-0 | V-0 | V-0 | V-0 | V-0 | V-0 |
| retardancy | | | | | | |
| (1.60 mm) | | | | | | |
| Water | 0.08 | 0.07 | 0.09 | 0.12 | 0.14 | 0.1 |
| absorption(%) | | | | | | |
| Peeling | 1.35-1.55 | 1.45-1.60 | 1.25-1.45 | 1.15-1.30 | 1.10-1.25 | 1.20-1.40 |
| strength range | | | | | | |
| (N/mm) | | | | | | |
| CTE (%) | 2.3 | 2.2 | 2.4 | 2.7 | 2.8 | 2.6 |
| Dielectric | 4.30 | 4.35 | 4.25 | 4.19 | 4.05 | 4.17 |
| constant | | | | | | |
| (1 GHz) | | | | | | |
| Dielectric loss | 0.0085 | 0.0078 | 0.0065 | 0.0065 | 0.0060 | 0.0055 |
| factor | | | | | | |
| (1 GHZ) | | | | | | |

TABLE 2

| | | | | Example | Example |
|---|---|---|---|---|---|
| | Example 7 | Example 8 | Example 9 | 10 | 11 |
| A1 | 80 | 80 | 60 | 50 | 50 |
| A2 | | | | | |
| B1 | 20 | 20 | | 50 | 50 |
| B2 | | | 10 | | |
| C1 | 30 | 30 | | 15 | 15 |
| C2 | | | 5 | | |
| D1 | 10 | 10 | | 20 | 20 |
| D2 | | | 10 | | |
| E1 | 2 | 65 | | | 30 |
| E2 | | | 50 | 20 | |
| E3 | | | | 30 | |
| E4 | | | | | |
| E5 | | | | | 20 |
| E6 | | | | | |
| F | 0.2 | 0.2 | 0.2 | 0.2 | 0.2 |
| Number of DSC peaks | 2 | 1 | 1 | 1 | 1 |
| Glass transition temperature | 158 | 174 | 162 | 169 | 167 |
| (Tg, ° C.) | | | | | |
| Flame retardancy (1.60 mm) | V-1 | V-0 | V-0 | V-0 | V-0 |
| Water absorption (%) | 0.23 | 0.11 | 0.12 | 0.09 | 0.09 |
| Peeling strength range (N/mm) | 0.60-0.85 | 1.05-1.25 | 1.20-1.35 | 1.25-1.45 | 1.25-1.45 |
| CTE (%) | 3.0 | 2.4 | 2.3 | 2.4 | 2.4 |
| Dielectric constant (1 GHz) | 3.90 | 4.25 | 4.20 | 4.25 | 4.25 |
| Dielectric loss factor | 0.0100 | 0.0058 | 0.0095 | 0.0065 | 0.0065 |
| (1 GHZ) | | | | | |

TABLE 3

| | Comp. | Comp. | Comp. | Comp. | Comp. | Comp. | Comp. |
|---|---|---|---|---|---|---|---|
| | Example 1 | Example 2 | Example 3 | Example 4 | Example 5 | Example 6 | Example 7 |
| A1 | 50 | | 50 | 50 | 50 | 50 | 90 |
| A2 | | 50 | | | | | |
| B1 | 50 | 50 | 50 | 50 | 50 | 50 | |
| B2 | | | | | | | 10 |
| C1 | | 15 | 15 | 15 | 15 | 15 | |
| C2 | | | | | | | 5 |
| D1 | 20 | 20 | 20 | 20 | 20 | 20 | |
| D2 | | | | | | | 10 |
| E1 | 50 | 50 | | | | | |
| E2 | | | | | | | 50 |
| E3 | | | | | | | |
| E4 | | | | 50 | | | |
| E5 | | | | | 50 | | |
| E6 | | | | | | 50 | |
| F | 0.2 | 0.2 | 0.2 | 0.2 | 0.2 | 0.2 | 0.2 |
| Number of | 1 | 1 | 2 | 2 | 2 | 2 | 1 |
| DSC peaks | | | | | | | |
| Glass transition | 162 | 175 | 156 | 168 | 156 | 157 | 159 |
| temperature | | | | | | | |
| (Tg, ° C.) | | | | | | | |
| Flame | V-0 | V-0 | V-0 | V-0 | V-0 | V-0 | V-1 |
| retardancy | | | | | | | |
| (1.60 mm) | | | | | | | |
| Water | 0.09 | 0.08 | 0.25 | 0.09 | 0.09 | 0.09 | 0.13 |
| absorption (%) | | | | | | | |
| Peeling | 1.25-1.45 | 1.30-1.45 | 0.95-1.15 | 0.80-0.90 | 0.80-0.90 | 0.80-0.90 | 0.95-1.05 |
| strength range | | | | | | | |
| (N/mm) | | | | | | | |
| CTE (%) | 2.4 | 2.3 | 2.8 | 2.4 | 2.4 | 2.4 | 2.4 |
| Dielectric | 4.25 | 4.05 | 3.9 | 4.25 | 4.25 | 4.25 | 4.2 |
| constant | | | | | | | |
| (1 GHz) | | | | | | | |
| Dielectric loss | 0.0090 | 0.0070 | 0.0085 | 0.0065 | 0.0065 | 0.0065 | 0.0100 |
| factor | | | | | | | |
| (1 GHZ) | | | | | | | |

The items and specific methods of the performance test are as follows.
(a) Glass transition temperature (Tg): tested according to the DSC method as stipulated under IPC-TM-650 2.4.25 in accordance with Differential Scanning calorimetry;
(b) Flame retardancy: tested according to the UL-94 standard;
(c) water absorption: tested according to the method as stipulated under IPC-TM-650 2.6.2.1;
(d) Number of DSC peaks: instrument manufacturer: TA, US; having a temperature rising rate of 10° C./min under N2 environment; the number of peaks at a temperature between 100° C.−250° C. on the DSC curve;
(e) Peeling strength: tested according to the method as stipulated under IPC-TM-650 2.4.8
(f) Coefficient of thermal expansion: tested according to the method IPC-TM-650 2.4.24;
(g) Dielectric constant and dielectric loss factor: testing dielectric constant and dielectric loss factor under 1 GHz by the method stipulated under IPC-TM-650 2.5.5.5.

The followings are the physical property analysises.

(1) By comparing Example 3 with Comparison Example 1, it can be seen that the addition of styrene maleic anhydride resin in Example 3 makes the prepared plates have a higher glass transition temperature, a lower dielectric loss factor and better dielectric properties than no addition of styrene maleic anhydride resin in Comparison Example 1. By comparing Example 3 with Comparison Example 2, it can be seen that the addition of alkylphenol epoxy resin in Example 3 makes the prepared plates have a lower dielectric loss factor and better dielectric properties than no addition of alkylphenol epoxy resin in Comparison Example 2. By comparing Example 3 with Comparison Example 3, it can be seen that the addition of an acidic filler having a pH of 2-6 in Example 3 makes less DSC peak number, and makes the prepared plates have a higher glass transition temperature, a lower water absorption, a higher peeling strength, and a lower dielectric loss factor than no addition of filler in Comparison Example 3.

According to the examples and comparison examples, it can be seen that the combination of alkylphenol epoxy resin and styrene maleic anhydride resin can achieve better dielectric properties. Moreover, the addition of the acidic filler could make up its defect of weak interlayer binding force, so as to reach synergistic effects of said three materials, effectively increase the dielectric properties and peeling strength stability of the resin composition and make the prepregs and printed circuit laminates have excellent comprehensive performances.

(2) By comparing Example 3 with Comparison Examples 4-6, it can be seen that the addition of an acidic filler having a pH of 2-6 in Example 3 makes less DSC peak number, and makes the prepared plates have a higher peeling strength than the addition of an acidic filler having a pH of higher than 6 in Comparison Examples 4-5;

the addition of an acidic filler having a pH of 2-6 in Example 3 makes less DSC peak number, and makes the prepared plates have a higher glass transition temperature and a higher peeling strength than the addition of an alkaline filler in Comparison Example 6.

By comparing Example 3 with Comparison Examples 4-6, it can be seen that the addition of an acidic filler having a pH of 2-6 in Example 3 greatly promotes the polymerization of benzoxazine and epoxy resin, decreases the curing temperature needed for the polymerization of benzoxazine and epoxy resin, and makes complete reaction of benzoxazine and epoxy resin. Meanwhile, it can also make the prepared laminates have a higher anti-stripping stability, a higher glass transition temperature, a low water absorption, a high heat resistance, a high bending strength and a better processability, and achieve a low coefficient of thermal expansion.

(3) By comparing Example 9 with Comparison Example 7, it can be seen that the lower content of alkylphenol epoxy resin in Example 9 can make the laminates have a higher glass transition temperature, the V-0 flame resistance level, a lower water absorption, a higher peeling strength, a lower coefficient of thermal expansion and a lower dielectric loss factor.

(4) By comparing Examples 5-6 with Comparison Examples 7-8, it can be seen that the addition of the acidic filler in an amount of 5-60 parts by weight in Examples 5-6 makes less DSC peak number, more excellent catalytic action, a higher glass transition temperature, the V-0 flame resistance level, a lower water absorption, a higher peeling strength and a lower coefficient of thermal expansion than the addition of the acidic filler in an amount of less than 5 parts by weight in Example 7; and the addition in Examples 5-6 makes a higher peeling strength and a better processability than the addition of the acidic filler in an amount of higher than 60 parts by weight in Example 8.

It could be concluded according to the aforesaid results that, while ensuring a higher glass transition temperature and excellent moisture and heat resistance, the halogen-free flame retardant resin composition of the present invention effectively improves the dielectric properties and the peeling strength stability of the resin composition, and provides the prepregs and copper clad laminates with excellent comprehensive performances.

It shall be noticed and understood that various amendments and improvements can be made to the present invention detailedly stated above, without departing from the spirit and scope of the present invention as set forth in the appended claims.

The applicant claims that the present invention describes the detailed process of the present invention, but the present invention is not limited to the detailed process of the present invention. That is to say, it does not means that the present invention shall be carried out with respect to the above-described detailed process of the present invention. Those skilled in the art shall know that any improvements to the present invention, equivalent replacements of the raw materials of the present invention, additions of auxiliary components, selections of any specific ways all fall within the protection scope and disclosure scope of the present invention.

1. A halogen-free flame retardant resin composition, characterized in based on the weight parts of solid components, comprising the following components:
(A) from 5 to 80 parts by weight of alkylphenol epoxy resin,
(B) from 10 to 80 parts by weight of benzoxazine resin,
(C) from 2 to 30 parts by weight of styrene maleic anhydride resin,
(D) from 1 to 30 parts by weight of a flame retardant, and
(E) from 0.5 to 100 parts by weight of an acidic filler having a pH of 2-6.

2. The halogen-free flame retardant resin composition claimed in claim 1, wherein said alkylphenol epoxy resin has the structure as follows 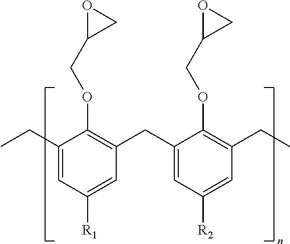
wherein R₁ and R₂ are each independently selected from substituted or unsubstituted linear alkyl or branched alkyl having a carbon atom number of 4-8, n is an integer of 2-20.

3. The halogen-free flame retardant resin composition claimed in claim 1, wherein said benzoxazine resin is anyone selected from the group consisting of bisphenol A type benzoxazine resin, dicyclopentadiene benzoxazine resin, bisphenol F type benzoxazine resin, phenolphthalein benzoxazine resin and MDA type benzoxazine resin, or a mixture of at least two selected therefrom.

4. The halogen-free flame retardant resin composition claimed in claim 1, wherein the styrene chain segment units and maleic anhydride chain segment units have a ratio of 8:1-1:1 in said styrene maleic anhydride resin.

5. The halogen-free flame retardant resin composition claimed in claim 1, wherein said acidic filler is anyone selected from the group consisting of silica powder, quartz powder, mica powder, clay, calcium oxalate and carbon black, or a mixture of at least two selected therefrom.

6. The halogen-free flame retardant resin composition claimed in claim 1, wherein the halogen-free flame retardant resin composition further comprises a non-acidic filler.

7. A process for preparing a halogen-free flame retardant resin composition, wherein comprising adding an acidic filler having a pH of 2-6 into a halogen-free flame retardant resin composition;
said halogen-free flame retardant resin composition comprises alkylphenol epoxy resin, benzoxazine resin and styrene maleic anhydride resin.

8. A prepreg comprising the halogen-free flame retardant resin composition claimed in claim 1, or the resin composition prepared according to the process claimed in claim 7.

9. A laminate comprising at least one sheet of the prepreg claimed in claim 8.

10. A printed circuit board comprising at least one sheet of the prepreg claimed in claim 8.

11. The halogen-free flame retardant resin composition claimed in claim 1, wherein said alkylphenol epoxy resin is in an amount of 10-35 parts by weight in the halogen-free flame retardant resin composition

12. The halogen-free flame retardant resin composition claimed in claim 1, wherein said benzoxazine resin is in an amount of 30-65 parts by weight in the halogen-free flame retardant resin composition.

13. The halogen-free flame retardant resin composition claimed in claim 1, wherein said styrene maleic anhydride resin is in an amount of 5-20 parts by weight in the halogen-free flame retardant resin composition;

14. The halogen-free flame retardant resin composition claimed in claim 1, wherein said flame retardant is anyone selected from the group consisting of resorcinol-bis(diphenyl phosphate), bisphenol A-bis(diphenyl phosphate), resorcinol-bis(2,6-dimethylphenyl phosphate), dimethyl methyl phosphonate and phosphazene compounds, or a mixture of at least two selected therefrom.

15. The halogen-free flame retardant resin composition claimed in claim 1, wherein said flame retardant is in an amount of 3-20 parts by weight in the halogen-free flame retardant resin composition.

16. The halogen-free flame retardant resin composition claimed in claim 1, wherein said acidic filler has a particle size of 50 nm-50 μm;

17. The halogen-free flame retardant resin composition claimed in claim 1, wherein said acidic filler has a pH of 4-6.

18. The halogen-free flame retardant resin composition claimed in claim 1, wherein said acidic filler is in an amount of 5-60 parts by weight in the halogen-free flame retardant resin composition.

19. The halogen-free flame retardant resin composition claimed in claim 1, wherein said non-acidic filler is anyone selected from the group consisting of calcium carbonate, calcium sulfate, alumina, barium sulfate, ceramic powder, talc powder and hydrotalcite, or a mixture of at least two selected therefrom.

20. The halogen-free flame retardant resin composition claimed in claim 1, wherein preferably, said non-acidic filler is added in an amount of 0-100 parts by weight;

21. The halogen-free flame retardant resin composition claimed in claim 1, wherein the halogen-free flame retardant resin composition further comprises from 0.1 to 1 part by weight of (F) a curing accelerator.

22. The halogen-free flame retardant resin composition claimed in claim 1, wherein said curing accelerator is anyone selected from the group consisting of imidazole accelerators and their derivatives, pyridine accelerators and Lewis acid accelerators, or a mixture of at least two selected therefrom.
